(19) United States
(12) Patent Application Publication
(10) Pub. No.: US 2025/0275098 A1
(43) Pub. Date: Aug. 28, 2025

(54) IMAGING APPARATUS

(71) Applicant: FUJIFILM Corporation, Tokyo (JP)

(72) Inventors: Tatsuya MOTOKI, Saitama-shi (JP); Takayuki SHIMIZU, Saitama-shi (JP); Masaaki TAKAGI, Saitama-shi (JP)

(73) Assignee: FUJIFILM Corporation, Tokyo (JP)

(21) Appl. No.: 19/054,898

(22) Filed: Feb. 16, 2025

(30) Foreign Application Priority Data
Feb. 26, 2024 (JP) 2024-026530

(51) Int. Cl. H05K 7/20; H04N 5/907; H04N 23/51

(52) U.S. Cl. CPC H05K 7/2039; H04N 5/907; H04N 23/51; H05K 7/20145

(57) ABSTRACT

An imaging apparatus includes: a housing including a first intake portion, a second intake portion, and an exhaust portion; an air cooling device provided inside the housing with an interval from the exhaust portion to generate an air flow from the first and second intake portions toward the exhaust portion; a rectifying member that is provided at an upstream side of the air flow with respect to the air cooling device and that rectifies intake air from the first intake portion and the second intake portion; a recording unit in which a recording medium to record imaging data is to be disposed; a first heat dissipation member provided at an upstream side of the air flow with respect to the air cooling device and including a heat dissipation fin for dissipating heat of the recording unit; and a heat dissipation sheet that dissipates heat of the recording unit.

### CROSS-REFERENCE TO RELATED APPLICATIONS

The present application claims priority under 35 U.S.C. § 119 to Japanese Patent Application No. 2024-026530 filed on Feb. 26, 2024. The above application is hereby expressly incorporated by reference, in its entirety, into the present application.

### BACKGROUND OF THE INVENTION

### 1. Field of the Invention

The present invention relates to an imaging apparatus.

### 2. Description of the Related Art

JP2020-113889A discloses an imaging apparatus comprising a main body portion that has a first intake hole at a lower right edge portion, a second intake hole at a lower left edge portion, an exhaust hole at an upper left edge portion, and a fan provided near the exhaust hole, an inner space of a first duct and a second duct is formed between the first intake hole and the second intake hole and the fan by an inverted Y-shaped duct separation wall, a heat sink portion for heat dissipation of an IC and a heat sink for heat dissipation of an imaging element are exposed in a first duct in a state of being disposed to be orthogonal to each other, and a socket case in which a medium case including a storage element inside is mounted is exposed in a second duct.

JP2019-097005A discloses a system camera comprising a heat dissipation module that is provided with a first ventilation port, a second ventilation port, an electric fan, a first exhaust port, and a second exhaust port, in which a heat sink that forms an air flow passage is disposed between the first ventilation port and the second ventilation port and the electric fan, a large number of heat dissipation fins and an inverted Y-shaped rectifying member are provided on the heat sink, and the heat dissipation module is connected to a display module that has a display device such as an LCD to be cooled.

JP2023-077022A discloses an imaging apparatus in which air sucked from an intake port into an inside of an imaging apparatus main body flows into an inner space of a duct unit formed by a duct base and a duct plate, passes through a plurality of heat dissipation duct fins formed on the duct base, passes through an inside of a cooling fan, and is discharged from an exhaust port, and a first media socket is thermally connected to the duct unit through a second heat conductive sheet, and heat generated in a recording medium is conducted to the duct unit through the first media socket and the second heat conductive sheet.

JP2022-135869A discloses an imaging apparatus comprising a main frame provided in a housing, in which the main frame supports an imaging unit including an imaging element and a heat sink, an image processing unit including a plurality of IC chips and a heat sink, and a writing unit including a connector into which a recording medium is inserted and a heat sink, a plurality of heat sinks and a fan are disposed in a duct-shaped air flow passage, and an extension length and the number of fins in each heat sink are individually determined based on a heat amount of a unit to be cooled and a surface area of each fin determined by an allowable temperature.

WO2019/171722A discloses an imaging apparatus in which a flow passage for cooling air is provided in an apparatus main body, the flow passage has a heat dissipation fin disposed on a downstream side of an intake hole, a cooling fan is disposed on a downstream side of the heat dissipation fin, a heat dissipation fin is disposed on a downstream side of the cooling fan, and an exhaust hole is disposed on a downstream side of the heat dissipation fin.

### SUMMARY OF THE INVENTION

One embodiment according to the technology of the present disclosure provides an imaging apparatus capable of improving cooling performance of a recording unit.

(1)

An imaging apparatus comprising:
a housing that includes a first intake portion, a second intake portion, and an exhaust portion;
an air cooling device that is provided inside the housing with an interval from the exhaust portion and that generates an air flow from the first intake portion and the second intake portion toward the exhaust portion;
a rectifying member that is provided on an upstream side of the air flow with respect to the air cooling device and that rectifies intake air from the first intake portion and the second intake portion;
a recording unit in which a recording medium that records imaging data is disposed;
a first heat dissipation member that is provided on the upstream side of the air flow with respect to the air cooling device and that includes a heat dissipation fin for dissipating heat of the recording unit; and
a second heat dissipation member that is a heat dissipation sheet that dissipates heat of the recording unit.
   (2)

The imaging apparatus according to (1),
in which the recording medium is inserted into and removed from the recording unit.
   (3)

The imaging apparatus according to (1) or (2),
in which the rectifying member is a protruding member.
   (4)

The imaging apparatus according to (3),
in which a height dimension of the protruding member is smaller than a width dimension of the protruding member.
   (5)

The imaging apparatus according to any one of (1) to (4),
in which the recording unit includes a medium accommodation portion in which the recording medium is accommodated, and a first electronic member that writes the imaging data to the recording medium accommodated in the medium accommodation portion,
the first heat dissipation member dissipates heat of the first electronic member, and
the second heat dissipation member dissipates heat of the medium accommodation portion.
   (6)

The imaging apparatus according to (5),
in which the heat dissipated from the medium accommodation portion includes heat generated from the recording medium.
   (7)

The imaging apparatus according to (5) or (6),
in which heat conduction occurs between the medium accommodation portion and the recording medium.
   (8)

The imaging apparatus according to any one of (1) to (7), further comprising:
a second electronic member that is different from the recording unit; and
a third heat dissipation member that is provided on the upstream side of the air flow with respect to the air cooling device and that includes a heat dissipation fin that dissipates heat of the second electronic member,
in which an arrangement direction of fins in the first heat dissipation member and an arrangement direction of fins in the third heat dissipation member are different from each other.
   (9)

The imaging apparatus according to (8),
in which the first heat dissipation member and the third heat dissipation member are disposed in the same space.
   (10)

The imaging apparatus according to any one of (1) to (9), comprising:
an imaging unit that includes an imaging element and a third electronic member; and
a fourth heat dissipation member that includes a heat dissipation fin for dissipating heat of the third electronic member,
in which the fourth heat dissipation member includes a first heat dissipation fin and a second heat dissipation fin, and
at least a part of the air cooling device is provided between the first heat dissipation fin and the second heat dissipation fin.
   (11)

The imaging apparatus according to any one of (1) to (10), comprising:
a second electronic member that is different from the recording unit;
a third heat dissipation member that is provided on the upstream side of the air flow with respect to the air cooling device and that includes a heat dissipation fin that dissipates heat of the second electronic member;
an imaging unit that includes an imaging element and a third electronic member; and
a fourth heat dissipation member that includes a heat dissipation fin for dissipating heat of the third electronic member,
in which an arrangement interval of fins in the first heat dissipation member, an arrangement interval of fins in the third heat dissipation member, and an arrangement interval of fins in the fourth heat dissipation member are different from each other.
   (12)

The imaging apparatus according to any one of (1) to (11),
in which the air cooling device is an air cooling fan.
   (13)

The imaging apparatus according to any one of (1) to (12),
in which the second heat dissipation member is a metal sheet or a graphite sheet.
   (14)

The imaging apparatus according to any one of (1) to (13),
in which the recording unit includes a medium accommodation portion in which the recording medium is accommodated and that has a lid portion,
the lid portion includes a fixing member that dissipates heat of the medium accommodation portion, and
the second heat dissipation member is connected to the fixing member.
   (15)

The imaging apparatus according to (14),
in which the second heat dissipation member is connected to the first heat dissipation member.
   (16)

An imaging apparatus comprising:
a housing that includes a first intake portion, a second intake portion, and an exhaust portion;
an air cooling device that is provided inside the housing with an interval from the exhaust portion and that generates an air flow from the first intake portion and the second intake portion toward the exhaust portion;
a rectifying member that is provided on an upstream side of the air flow with respect to the air cooling device and that rectifies intake air from the first intake portion and the second intake portion;
a recording unit in which a recording medium that records imaging data is inserted into and removed from; and
a second heat dissipation member that is a heat dissipation sheet that dissipates heat of the recording unit.

According to the present invention, it is possible to provide an imaging apparatus capable of improving cooling performance of a recording unit.

### BRIEF DESCRIPTION OF THE DRAWINGS

FIG. 1 is a simplified perspective view showing an example of an imaging apparatus 100 in the present embodiment as viewed from the front left side.

FIG. 2 is a simplified perspective view of the imaging apparatus 100 shown in FIG. 1 as viewed from the front right side.

FIG. 3 is a diagram showing an example of a flow of air in a housing 110.

FIG. 4 is a view of a heat dissipation member provided in the housing 110 as viewed from a rear side of the imaging apparatus 100.

FIG. 5 is a view of a heat dissipation member provided in the housing 110 as viewed from a left side of the imaging apparatus 100.

FIG. 6 is a perspective view showing an example of a disposition relationship between a fourth heat dissipation member 118 and an air cooling fan 111.

FIG. 7 is a perspective view showing an example of a disposition relationship between a first heat dissipation member 113 and a third heat dissipation member 116.

FIG. 8 is a diagram showing a first modification example of a configuration of the first heat dissipation member 113.

FIG. 9 is a diagram showing a second modification example of the configuration of the first heat dissipation member 113.

FIG. 10 is a diagram showing a first attachment example of the second heat dissipation member 114.

FIG. 11 is a diagram showing a second attachment example of the second heat dissipation member 114.

FIG. 12 is a diagram showing a third attachment example of the second heat dissipation member 114.

FIG. 13 is a diagram showing a fourth attachment example of the second heat dissipation member 114.

FIG. 14 is a diagram showing a state where the lid portion 119 shown in FIG. 13 is opened.

### DESCRIPTION OF THE PREFERRED EMBODIMENTS

Hereinafter, an example of an embodiment of the present invention will be described with reference to the drawings. In the present embodiment, the terms “upward direction”, “downward direction”, “leftward direction”, “rightward direction”, “forward direction”, and “backward direction” are used, but these directions are relative directions set for convenience of description for the imaging apparatus shown in each drawing.

### Imaging Apparatus of Embodiment

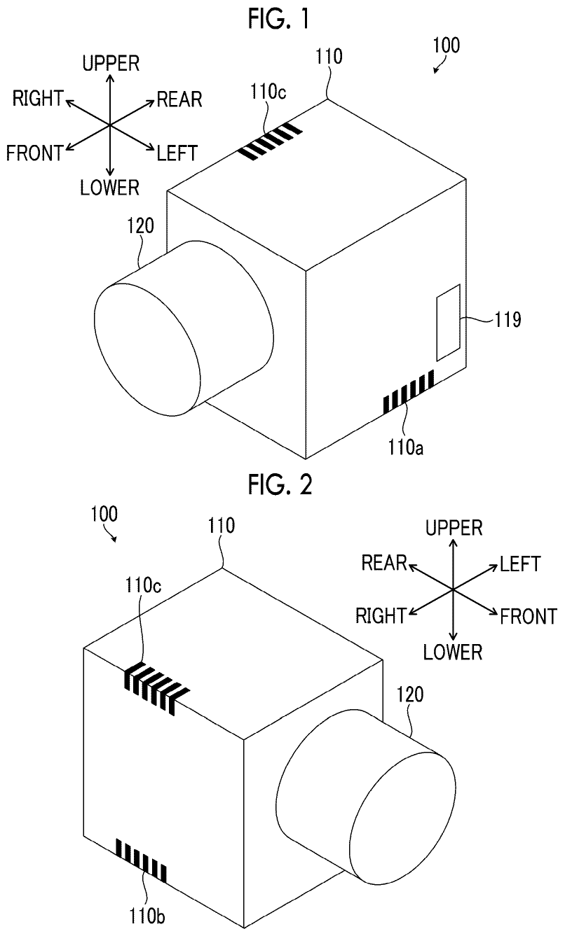

FIG. 1 is a simplified perspective view showing an example of the imaging apparatus 100 in the present embodiment as viewed from the front left side. FIG. 2 is a simplified perspective view of the imaging apparatus 100 shown in FIG. 1 as viewed from the front right side. Examples of the imaging apparatus include a digital camera or a single-lens reflex camera capable of capturing a motion picture. As shown in FIGS. 1 and 2, the imaging apparatus 100 comprises a housing 110 that constitutes a main body portion of the imaging apparatus 100, and a lens 120 attached to the housing 110.

The housing 110 is formed in a substantially cubic shape. A first intake portion 110a is provided at a lower left end portion of the housing 110. In addition, a second intake portion 110b is provided at a lower right end portion of the housing 110. The first intake portion 110a and the second intake portion 110b are opening portions capable of taking in air from the outside of the housing 110 into the inside of the housing 110. The first intake portion 110a and the second intake portion 110b are composed of, for example, a plurality of slit-shaped openings.

In addition, an exhaust portion 110c is provided at an upper right end portion of the housing 110. The exhaust portion 110c is an opening portion through which air inside the housing 110 can be discharged to the outside of the housing 110. The exhaust portion 110c is composed of, for example, a plurality of slit-shaped openings.

The opening constituting the exhaust portion 110c is formed, for example, from an upper wall of the housing 110 to a right side wall of the housing 110. Although not shown, the opening constituting the first intake portion 110a is formed from the left side wall to the lower wall, and the opening constituting the second intake portion 110b is formed from the right side wall to the lower wall.

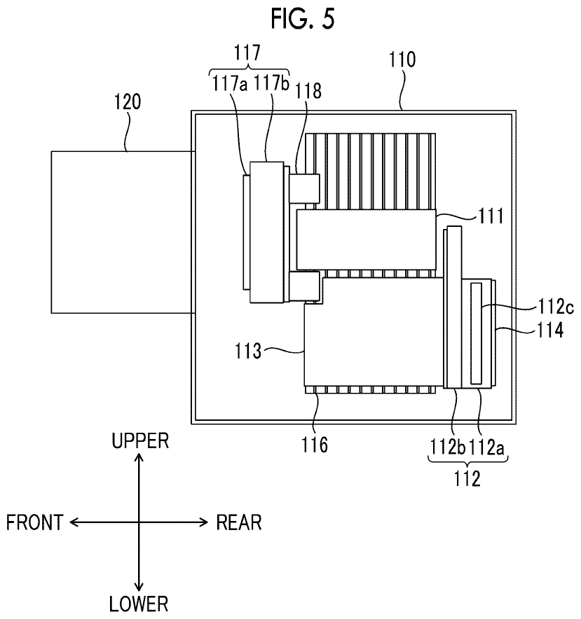

In addition, a lid portion 119 of a recording unit 112 (described below with reference to FIG. 5) into which a recording medium is inserted into and removed from is provided on a lower portion of the left side wall of the housing 110. The recording medium records the imaging data of the imaging apparatus 100.

The lens 120 is attached to a front side (front surface) of the housing 110. The lens 120 can be replaced. The lens 120 includes at least an imaging lens such as a focus lens or a zoom lens.

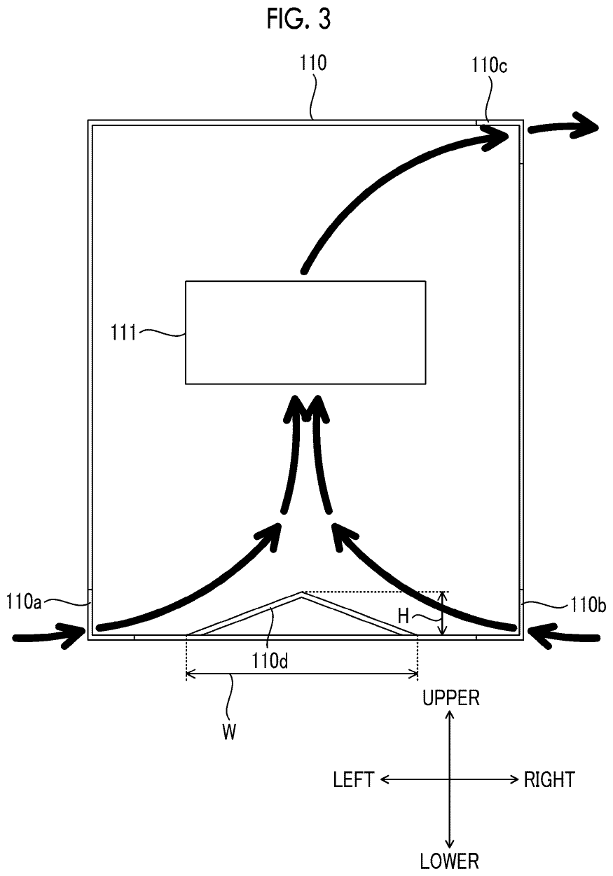

FIG. 3 is a diagram showing an example of a flow of air in the housing 110. In FIG. 3, components unnecessary for the description are omitted in order to make the flow of air easy to see. As shown in FIG. 3, an air cooling fan 111, which is an example of an “air cooling device” according to the embodiment of the present invention, is provided in a substantially central portion of a housing 110. The air cooling fan 111 is provided with an interval from an exhaust portion 110c provided at an upper right end portion of the housing 110. The description that the air cooling fan 111 is provided with an interval from an exhaust portion 110c means that the air cooling fan 111 is not provided in the vicinity of the exhaust portion 110c. The expression “provided with an interval” means, for example, that there is a space between the air cooling fan 111 and the exhaust portion 110c, in which a heat generating body such as an electronic component can be disposed, or there is a space in which the heat generating body is actually disposed. The air cooling device may be, for example, a blower or a compressor.

The air cooling fan 111 generates an air flow from the first intake portion 110a and the second intake portion 110b toward the exhaust portion 110c in the housing 110. For example, the air cooling fan 111 rotates to allow air outside the housing 110 to flow into the housing 110 from the first intake portion 110a provided at the lower left end portion of the housing 110 and the second intake portion 110b provided at the lower right end portion of the housing 110, to pass through the air cooling fan 111, and to flow out of the housing 110 from the exhaust portion 110c provided at the upper right end portion of the housing 110, as indicated by the solid line arrow in FIG. 3.

In addition, a rectifying member 110d for rectifying a flow of air in the housing 110 is provided at a central lower end portion in the housing 110. The rectifying member 110d is provided on the upstream side (the lower side in FIG. 3) of the air flow with respect to the air cooling fan 111 indicated by the solid line arrow in FIG. 3. The upstream side of the air flow refers to the first intake portion 110a and the second intake portion 110b side in the housing 110 (not the exhaust portion 110c side). The rectifying member 110d is a protruding member that protrudes from the lower wall of the housing 110 toward the upper wall direction. The height dimension H of the rectifying member 110d is smaller than the width dimension W. The rectifying member 110d rectifies the intake air from the first intake portion 110a and the second intake portion 110b. The rectifying member 110d rectifies the air flowing into the housing 110 from the first intake portion 110a and the second intake portion 110b to rise in the direction of the air cooling fan 111 as indicated by a solid line arrow.

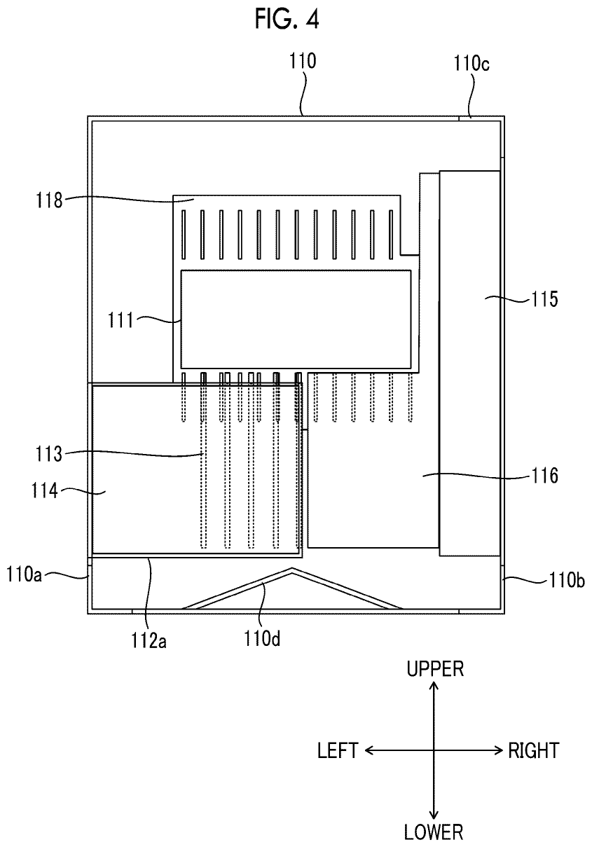

FIG. 4 is a view of a heat dissipation member provided in the housing 110 as viewed from a rear side of the imaging apparatus 100. FIG. 5 is a view of the heat dissipation member provided in the housing 110 as viewed from the left side of the imaging apparatus 100. As shown in FIGS. 4 and 5, a first heat dissipation member 113, a second heat dissipation member 114, a third heat dissipation member 116, and a fourth heat dissipation member 118 are provided in the housing 110. In addition, a recording unit 112, a main board 115, and an imaging unit 117 are provided in the housing 110.

The first heat dissipation member 113 and the second heat dissipation member 114 are heat dissipation members attached to the recording unit 112. The first heat dissipation member 113 is composed of a heat sink having a plurality of heat dissipation fins. The first heat dissipation member 113 is provided on the upstream side (the lower side in FIGS. 4 and 5) of the air flow indicated by the solid line arrow in FIG. 3 with respect to the air cooling fan 111. The second heat dissipation member 114 is composed of a heat transfer sheet or a heat dissipation sheet having high heat transfer properties. The second heat dissipation member is, for example, a metal sheet, a graphite sheet, a copper foil tape, and an aluminum tape that can be attached to the recording unit 112.

The recording unit 112 is a device into which a recording medium for recording the imaging data of the imaging apparatus 100 is inserted in and removed from. The recording unit 112 is provided at a lower left portion of the rear portion in the housing 110. In the present example, the recording unit 112 is provided on the rear side of the air cooling fan 111 along the rear wall of the housing 110. The recording unit 112 includes a medium accommodation portion 112a and a first electronic member 112b.

The medium accommodation portion 112a is a portion in which the recording medium is accommodated. The medium accommodation portion 112a is provided with an insertion port 112c for inserting in and pulling out a recording medium. The medium accommodation portion 112a is disposed such that the insertion port 112c is exposed to the outside from the left side wall of the housing 110. The lid portion 119 shown in FIG. 1 is attached to the insertion port 112c of the medium accommodation portion 112a. The first electronic member 112b is, for example, an electronic board that performs processing of writing imaging data to the recording medium accommodated in the medium accommodation portion 112a. The recording medium is, for example, a CFexpress Type B or XQD memory card.

The first heat dissipation member 113 and the second heat dissipation member 114 absorb heat emitted from the recording unit 112 and dissipate the heat into the air to cool the recording unit 112. The first heat dissipation member 113 is attached to the first electronic member 112b of the recording unit 112 and dissipates heat of the first electronic member 112b. The second heat dissipation member 114 is attached to the medium accommodation portion 112a of the recording unit 112 and dissipates heat of the medium accommodation portion 112a. Heat conduction occurs between the medium accommodation portion 112a and the recording medium accommodated therein. Therefore, the heat generated by the recording medium is included in the heat dissipated from the medium accommodation portion 112a. The second heat dissipation member 114 dissipates heat of the medium accommodation portion 112a and the recording medium accommodated therein.

The third heat dissipation member 116 is a heat dissipation member attached to the main board 115 which is an example of a “second electronic member” according to the embodiment of the present invention, and is configured with a heat sink having a plurality of heat dissipation fins. The third heat dissipation member 116 is provided on the upstream side (the lower side in FIGS. 4 and 5) of the air flow with respect to the air cooling fan 111 indicated by the solid line arrow in FIG. 3. The third heat dissipation member 116 is disposed in the same space as the first heat dissipation member 113 on the upstream side of the air flow with respect to the air cooling fan 111.

The main board 115 is, for example, an electronic board that performs imaging control, image processing, and the like of the imaging apparatus 100. The main board 115 is provided at a right end portion in the housing 110. In the present example, the main board 115 is provided on the right side of the air cooling fan 111 along the right side wall of the housing 110. The third heat dissipation member 116 absorbs heat emitted from the main board 115 and dissipates the heat into the air to cool the main board 115.

The fourth heat dissipation member 118 is a heat dissipation member attached to the imaging unit 117, and is composed of a heat sink having a plurality of heat dissipation fins. A part of the fourth heat dissipation member 118 is provided on the upstream side (lower side in FIGS. 4 and 5) of the air flow with respect to the air cooling fan 111 indicated by the solid line arrow in FIG. 3.

The imaging unit 117 includes an imaging element 117a and a third electronic member 117b. The imaging unit 117 is provided at a front portion in the housing 110 to face the lens 120. In the present example, the imaging unit 117 is provided on the front side of the air cooling fan 111 along the front wall of the housing 110. The imaging element 117a and the third electronic member 117b are configured such that the third electronic member 117b is disposed on a rear surface side of the imaging element 117a in an optical axis direction of the lens 120. The light incident from the lens 120 is imaged on the imaging element 117a.

The imaging element 117a is composed of, for example, a charge coupled device (CCD) image sensor or a Complementary Metal Oxide Semiconductor (CMOS) image sensor. The third electronic member 117b includes a signal processing circuit that performs sampling processing, digital conversion processing, and the like on the captured image signal output from the imaging element 117a. In addition, the third electronic member 117b includes an image processing unit that performs digital signal processing on the captured image signal after processing by the signal processing circuit to generate captured image data, for example, in a joint photographic experts group (JPEG) format.

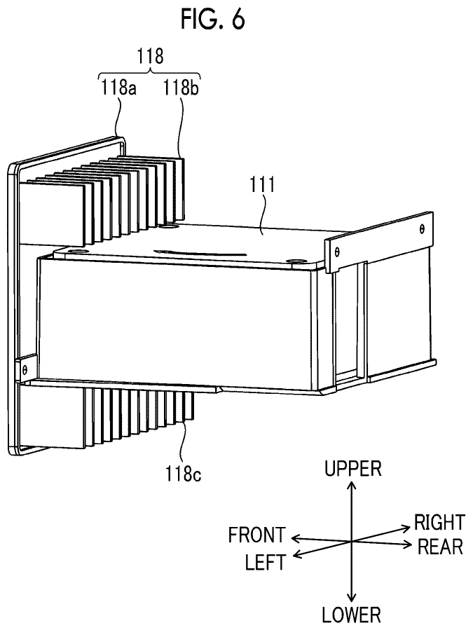

FIG. 6 is a perspective view showing an example of a disposition relationship between the fourth heat dissipation member 118 and the air cooling fan 111. As shown in FIG. 6, the fourth heat dissipation member 118 has a base portion 118a, a first heat dissipation fin 118b, and a second heat dissipation fin 118c.

The base portion 118a is a plate-shaped member to which the third electronic member 117b is attached. The third electronic member 117b is attached to a surface on a side on which the lens 120 is provided (surface of the front side), of the base portion 118a disposed in the housing 110. The base portion 118a is made of a metal member such as aluminum or copper having high thermal conductivity.

The first heat dissipation fin 118b and the second heat dissipation fin 118c are provided on a surface of the base portion 118a on a side opposite to a side to which the third electronic member 117b is attached (surface on the rear side). The first heat dissipation fin 118b is a heat dissipation fin provided on an upper portion of a surface of the base portion 118a on a rear side, and is composed of a plurality of fins extending in parallel to each other from the base portion 118a. The second heat dissipation fin 118c is a heat dissipation fin provided on a lower portion of the surface of the base portion 118a on the rear side, and is composed of a plurality of fins extending in parallel to each other from the base portion 118a, similarly to the first heat dissipation fin 118b. The plurality of fins of the first heat dissipation fin 118b and the second heat dissipation fin 118c are arranged in the left-right direction.

The first heat dissipation fin 118b and the second heat dissipation fin 118c are fins that dissipate heat of the third electronic member 117b. The fins for dissipating heat of the third electronic member 117b are heat conduction members in which the first heat dissipation fin 118b and the second heat dissipation fin 118c are thermally connected to the third electronic member 117b. For example, the first heat dissipation fin 118b and the second heat dissipation fin 118c may be in direct contact with the third electronic member 117b, or may be connected to the third electronic member 117b via another heat conduction member. The first heat dissipation fin 118b and the second heat dissipation fin 118c of the present example are connected to the third electronic member 117b via the base portion 118a. The first heat dissipation fin 118b and the second heat dissipation fin 118c dissipate the heat conducted from the third electronic member 117b to the base portion 118a.

At least a part of the air cooling fan 111 is provided between the first heat dissipation fin 118b and the second heat dissipation fin 118c. The description that “at least a part of the air cooling fan 111 is provided between the first heat dissipation fin 118b and the second heat dissipation fin 118c” means that the first heat dissipation fin 118b and the second heat dissipation fin 118c are provided in a blowing direction of the air cooling fan 111. In the present example, a part of the air cooling fan 111 on the front side is provided between the first heat dissipation fin 118b and the second heat dissipation fin 118c. With such disposition, the first heat dissipation fin 118b and the second heat dissipation fin 118c can discharge the heat of the third electronic member 117b into the air flow of the air cooling fan 111 (in the air flow indicated by the solid line arrow in FIG. 3).

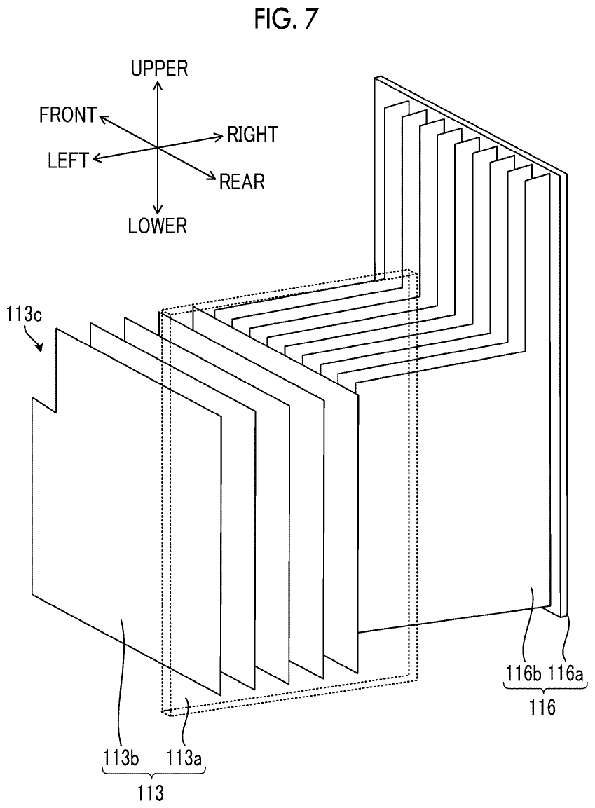

FIG. 7 is a perspective view showing an example of a disposition relationship between the first heat dissipation member 113 and the third heat dissipation member 116. As shown in FIG. 7, the first heat dissipation member 113 has a base portion 113a and a heat dissipation fin 113b. In addition, the third heat dissipation member 116 has a base portion 116a and a heat dissipation fin 116b.

A base portion 113a of the first heat dissipation member 113 is a plate-shaped member to which the first electronic member 112b of the recording unit 112 is attached. The first electronic member 112b is attached to a surface on a side on which the rear wall of the housing 110 is provided (surface on the rear side), of the base portion 113a disposed in the housing 110. The base portion 113a is made of a metal member such as aluminum or copper having high thermal conductivity.

The heat dissipation fin 113b is provided on a surface on a side opposite to a side on which the first electronic member 112b is attached (surface on the front side) of the base portion 118a, and are composed of a plurality of fins extending in parallel to each other from the base portion 113a. The heat dissipation fin 113b is a fin that dissipates heat of the first electronic member 112b. The fin for dissipating heat of the first electronic member 112b refers to a heat conduction member in which the heat dissipation fin 113b is thermally connected to the first electronic member 112b. For example, the heat dissipation fin 113b may be in direct contact with the first electronic member 112b or may be connected to the first electronic member 112b via another heat conduction member. The heat dissipation fin 113b of the present example is connected to the first electronic member 112b via the base portion 113a. The heat dissipation fin 113b dissipates heat conducted from the first electronic member 112b to the base portion 118a. As described in FIGS. 4 and 5, the first heat dissipation member 113 is provided on the upstream side of the air flow with respect to the air cooling fan 111. However, the heat dissipation fin 113b of the first heat dissipation member 113 only need to be provided on the upstream side of the air flow with respect to the air cooling fan 111, and the base portion 118a may extend to the height of the air cooling fan 111.

A base portion 116a of the third heat dissipation member 116 is a plate-shaped member to which the main board 115 is attached. The main board 115 is attached to a surface on a side on which the right wall of the housing 110 is provided (surface on the right side), of the base portion 116a disposed in the housing 110. The base portion 116a is made of a metal member such as aluminum or copper having high thermal conductivity.

The heat dissipation fins 116b are provided on a surface on a side opposite to a side of the base portion 116a to which the main board 115 is attached (surface on the left side) and are composed of a plurality of fins extending in parallel to each other from the base portion 116a. The heat dissipation fin 116b is a fin that dissipates heat of the main board 115. The fin that dissipates heat of the main board 115 is heat conduction member in which the heat dissipation fin 116b is thermally connected to the main board 115. For example, the heat dissipation fin 116b may be in direct contact with the main board 115 or may be connected to the main board 115 via another heat conduction member. The heat dissipation fin 116b of the present example is connected to the main board 115 via the base portion 116a. The heat dissipation fin 116b dissipates heat conducted from the main board 115 to the base portion 116a.

An arrangement direction of the heat dissipation fins 113b in the first heat dissipation member 113 is different from an arrangement direction of the heat dissipation fins 116b in the third heat dissipation member 116. The arrangement direction of the heat dissipation fins 113b and the arrangement direction of the heat dissipation fins 116b are different from each other by, for example, about 90°. The plurality of fins in the heat dissipation fins 113b are arranged in the left-right direction. On the other hand, the plurality of fins in the heat dissipation fins 116b are arranged in the front-rear direction.

The arrangement interval of the heat dissipation fins 113b in the first heat dissipation member 113, the arrangement interval of the heat dissipation fins 116b in the third heat dissipation member 116, and the arrangement intervals of the first heat dissipation fins 118b and the second heat dissipation fins 118c (see FIG. 6) in the fourth heat dissipation member 118 are different from each other.

The arrangement direction of the heat dissipation fins 113b in the first heat dissipation member 113 and the arrangement direction of the first heat dissipation fins 118b and the second heat dissipation fins 118c in the fourth heat dissipation member 118 are the same left-right direction. However, the arrangement interval of the heat dissipation fins 113b and the arrangement interval of the first heat dissipation fins 118b and the second heat dissipation fins 118c are different from each other. Therefore, it is difficult to dispose the heat dissipation fins to be alternated so that the heat dissipation fins of both the heat dissipation members do not interfere with each other. Therefore, the cutout portion 113c is formed in the heat dissipation fins 113b of the first heat dissipation member 113 so that the heat dissipation fins do not interfere with each other regardless of the difference in the arrangement interval between the two heat dissipation fins.

As described above, the imaging apparatus 100 of the present embodiment comprises the first heat dissipation member 113 that includes the heat dissipation fin 113b that is provided on the upstream side of the air flow with respect to the air cooling fan 111 and that dissipates heat of the first electronic member 112b in the recording unit 112, and the second heat dissipation member 114 consisting of the heat dissipation sheet that dissipates heat of the medium accommodation portion 112a in the recording unit 112. According to this configuration, the heat generated in the first electronic member 112b of the recording unit 112 is conducted to the first heat dissipation member 113, and the heat generated in the medium accommodation portion 112a of the recording unit 112 is conducted to the second heat dissipation member 114, and the first heat dissipation member 113 and the second heat dissipation member 114 to which the heat has been conducted can be effectively cooled by a low temperature air flow generated by the air cooling fan 111 using the outside air suctioned from the first intake portion 110a and the second intake portion 110b. In this way, by performing the heat dissipation of the recording unit 112 using the first heat dissipation member 113 and the second heat dissipation member 114, the cooling property of the recording unit 112 can be improved.

In addition, the imaging apparatus 100 further comprises a third heat dissipation member 116 that is provided on an upstream side of the air flow with respect to the air cooling fan 111 and includes a heat dissipation fin 116b that dissipates heat of the main board 115, and an arrangement direction of the heat dissipation fins 113b of the first heat dissipation member 113 dissipating heat of the recording unit 112 and an arrangement direction of the heat dissipation fins 116b of the third heat dissipation member 116 dissipating heat of the main board 115 are different from each other. According to this configuration, it is possible to suppress interference between the heat dissipation from the heat dissipation fin 113b in the first heat dissipation member 113 and the heat dissipation from the heat dissipation fin 116b in the third heat dissipation member 116. As a result, the cooling property of the recording unit 112 can be further improved.

In addition, the imaging apparatus 100 further comprises a fourth heat dissipation member 118 that includes a first heat dissipation fin 118b and a second heat dissipation fin 118c that dissipate heat of the third electronic member 117b in the imaging unit 117, and at least a part of the air cooling fan 111 is provided between the first heat dissipation fin 118b and the second heat dissipation fin 118c. According to this configuration, it is possible to effectively use the space in the housing 110, and to reduce the size of the imaging apparatus 100.

In addition, in the imaging apparatus 100, the arrangement interval of the heat dissipation fins 113b in the first heat dissipation member 113, the arrangement interval of the heat dissipation fins 116b in the third heat dissipation member 116, and the arrangement interval of the first heat dissipation fins 118b and the second heat dissipation fins 118c in the fourth heat dissipation member 118 are different from each other. According to this configuration, the cooling property of the recording unit 112 having a large amount of heat dissipation can be further improved by changing the arrangement interval of the heat dissipation fins in accordance with the amount of heat dissipated by the electronic member attached to each heat dissipation member and the flow passage of the cooling air. In addition, in the imaging apparatus 100, since the cutout portion 113c is provided in the heat dissipation fin 113b of the first heat dissipation member 113, the interference between the heat dissipation fin 113b and the first heat dissipation fin 118b and the second heat dissipation fin 118c of the fourth heat dissipation member 118 can be suppressed, and the heat dissipation property of the recording unit 112 by the first heat dissipation member 113 can be maintained.

### Modification Example of First Heat Dissipation Member 113

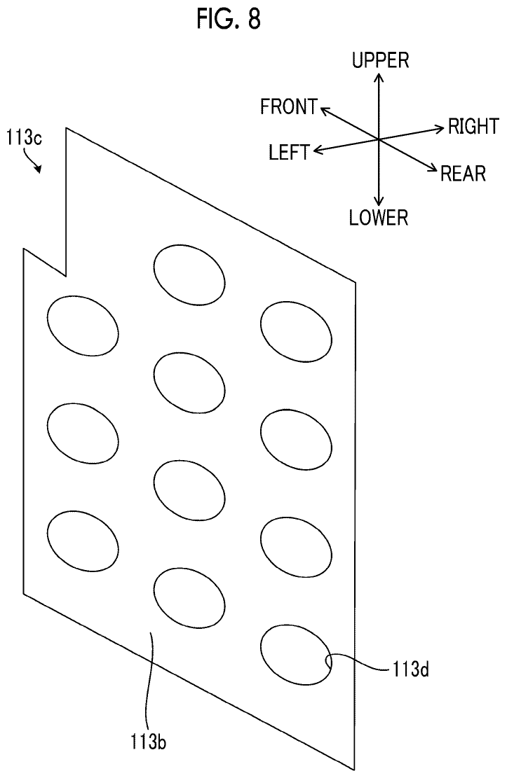

FIG. 8 is a diagram showing a first modification example of the configuration of the first heat dissipation member 113. As shown in FIG. 8, the heat dissipation fin 113b of the first heat dissipation member 113 may be provided with a hole 113d in each heat dissipation fin 113b. In the first modification example, a plurality of circular holes are provided as the hole 113d. The shape and the number of the hole are not particularly limited. In addition, the present invention is not limited to the first heat dissipation member 113, and the heat dissipation fins of other heat dissipation members (the third heat dissipation member 116 and the fourth heat dissipation member 118) may also be provided with holes in the same manner.

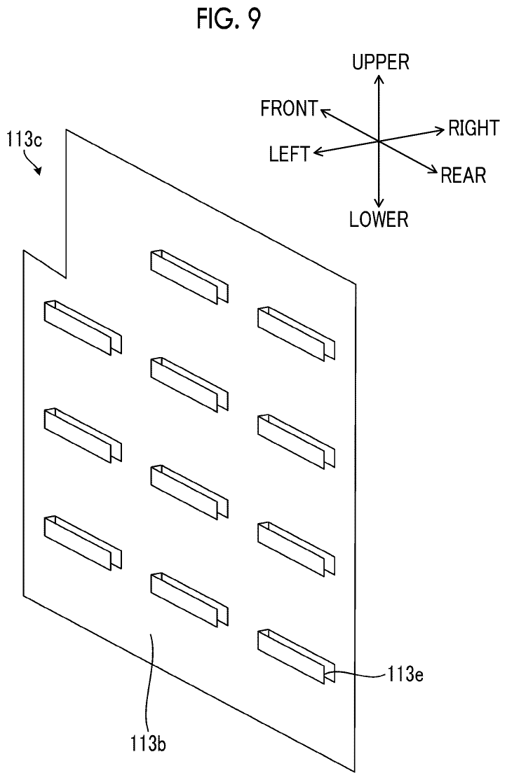

FIG. 9 is a diagram showing a second modification example of the configuration of the first heat dissipation member 113. As shown in FIG. 9, a cut and raised portion 113e may be provided in each of the heat dissipation fins 113b of the first heat dissipation member 113. The cut and raised portion 113e is formed by processing of cutting the heat dissipation fin 113b by punching or the like and bending the cut portion to form the cut portion into, for example, an L-shape. The cut and raised portion may be provided in the heat dissipation fins of the third heat dissipation member 116 and the fourth heat dissipation member 118 in the same manner.

As described above, by providing the hole 113d or the cut and raised portion 113e in the heat dissipation fin 113b of the first heat dissipation member 113, it is possible to prevent the flow of heat generated by the first electronic member 112b (recording unit 112) from stagnating between the heat dissipation fins 113b, and it is possible to improve the heat dissipation effect.

### Attachment Example of Second Heat Dissipation Member 114

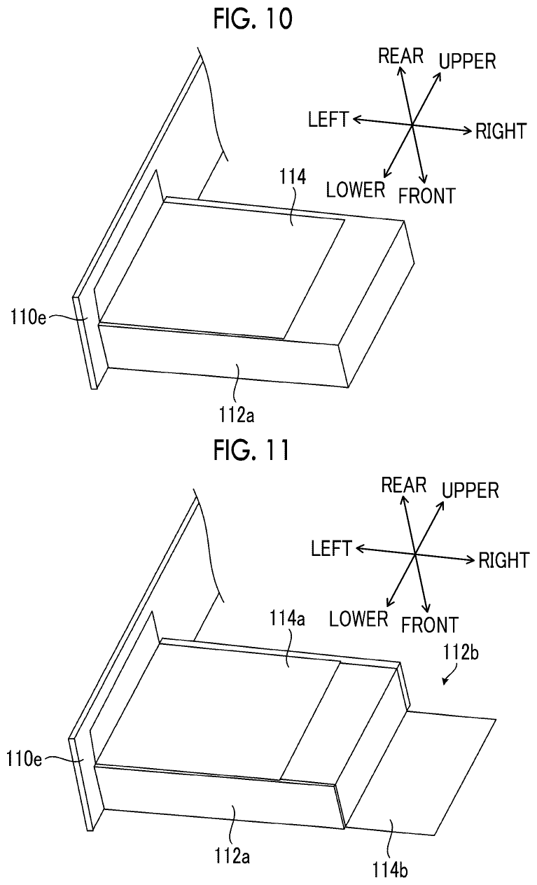

FIG. 10 is a view showing a first attachment example of the second heat dissipation member 114. As shown in FIG. 10, a graphite sheet, which is an example of the second heat dissipation member 114, is attached over a left wall 110e of the housing 110 and the medium accommodation portion 112a. Specifically, the second heat dissipation member 114 is attached over the inner side surface of the left wall 110e to the upper surface of the medium accommodation portion 112a. As a result, heat generated in the medium accommodation portion 112a can be conducted to the wall 110e of the housing 110 through the graphite sheet, and the heat dissipation effect can be improved.

FIG. 11 is a diagram showing a second attachment example of the second heat dissipation member 114. As shown in FIG. 11, a plurality of second heat dissipation members 114 (for example, graphite sheets) may be stacked and attached. For example, another second heat dissipation member 114b may be attached between the second heat dissipation member 114a attached over the left wall 110e of the housing 110 and the medium accommodation portion 112a, and the medium accommodation portion 112a.

In addition, the second heat dissipation member 114b, which is stacked and attached, may be extended from the medium accommodation portion 112a, and the extended portion may be attached to another portion of the housing 110 or the first electronic member 112b of the recording unit 112. In the case of the present example, the second heat dissipation member 114b, which is stacked and attached, is attached over the medium accommodation portion 112a and the first electronic member 112b. In the present example, two graphite sheets are attached. However the present invention is not limited thereto. For example, one graphite sheet may be attached over the housing 110, the medium accommodation portion 112a, and the first electronic member 112b. According to the second attachment example, the heat generated in the medium accommodation portion 112a can be conducted through the graphite sheet, not only to the housing 110, but also to the first heat dissipation member 113 attached to the first electronic member 112b through the graphite sheet and the first electronic member 112b, and thus the heat dissipation effect can be further improved.

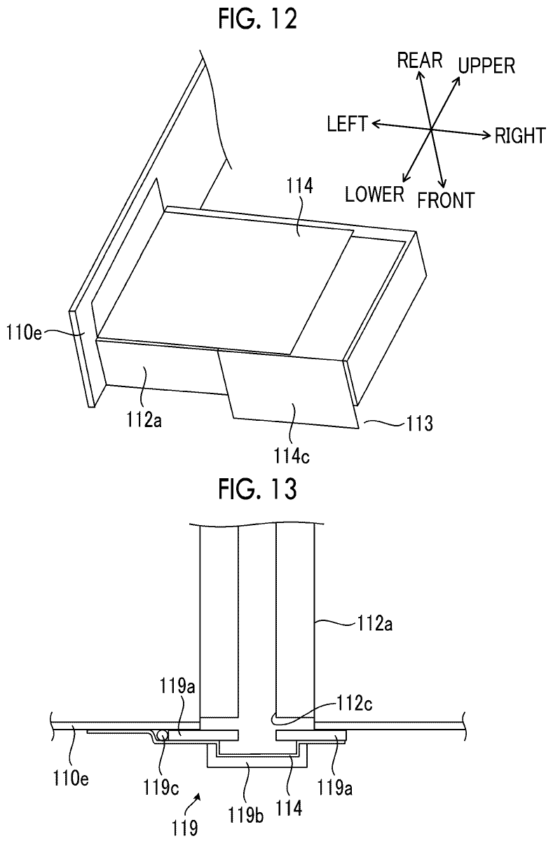

FIG. 12 is a diagram showing a third attachment example of the second heat dissipation member 114. As shown in FIG. 12, the second heat dissipation member 114c, which is stacked and attached on the second heat dissipation member 114a (for example, the graphite sheet), may be extended to the lower side of the medium accommodation portion 112a so as to be attached over the first heat dissipation member 113 to which the first electronic member 112b is attached. According to the third attachment example, the heat generated in the medium accommodation portion 112a can be conducted through the graphite sheet not only to the housing 110, but also to the first heat dissipation member 113, and thus the heat dissipation effect can be further improved.

FIG. 13 is a diagram showing a fourth attachment example of the second heat dissipation member 114. As shown in FIG. 13, the second heat dissipation member 114 (for example, a graphite sheet) may be attached to the lid portion 119 of the medium accommodation portion 112a.

The lid portion 119 rotates around the rotary shaft 119c so as to be attached to be openable and closable with respect to the left wall 110e of the housing 110. The lid portion 119 of FIG. 13 shows a closed state. The lid portion 119 includes a fixing member 119a that dissipates heat of the medium accommodation portion 112a and a resin cover 119b that is provided in a central portion of the fixing member 119a. The fixing member 119a is composed of, for example, a metal member such as aluminum or copper having high thermal conductivity.

The second heat dissipation member 114 is attached over the left wall 110e of the housing 110 and the lid portion 119. Specifically, the second heat dissipation member 114 is attached over the outer side surface of the left wall 110e, the outer side surface of the fixing member 119a, and the inner side surface of the resin cover 119b. The second heat dissipation member 114 is connected to the fixing member 119a.

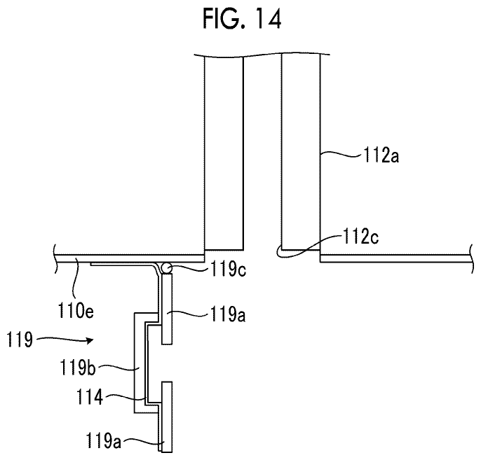

FIG. 14 is a view showing a state in which the lid portion 119 shown in FIG. 13 is opened. As shown in FIG. 14, by opening the lid portion 119, the insertion port 112c of the medium accommodation portion 112a is exposed from the left wall 110e of the housing 110, and the recording medium can be inserted in and removed from. According to the third attachment example, the heat generated in the medium accommodation portion 112a can be conducted to the wall 110e of the housing 110 via the graphite sheet attached to the lid portion 119, and the heat dissipation effect can be improved.

### EXPLANATION OF REFERENCES

100: imaging apparatus
110: housing
110a: first intake portion
110b: second intake portion
110c: exhaust portion
110d: rectifying member
110e: wall
111: air cooling fan
112: recording unit
112a: medium accommodation portion
112b: first electronic member
112c: insertion port
113: first heat dissipation member
113a, 116a, 118a: base portion
113b, 116b: heat dissipation fin
113c: cutout portion
113d: hole
113e: cut and raised portion
114, 114a, 114b, 114c: second heat dissipation member
115: main board
116: third heat dissipation member
117: imaging unit
117a: imaging element
117b: third electronic member
118: fourth heat dissipation member
118b: first heat dissipation fin
118c: second heat dissipation fin
119: lid portion
119a: fixing member
119b: resin cover
119c: rotation shaft
120: lens

What is claimed is:

1. An imaging apparatus comprising:
a housing that includes a first intake portion, a second intake portion, and an exhaust portion;
an air cooling device that is provided inside the housing with an interval from the exhaust portion and that is configured to generate an air flow from the first intake portion and the second intake portion toward the exhaust portion;
a rectifying member that is provided at an upstream side of the air flow with respect to the air cooling device and that rectifies intake air from the first intake portion and the second intake portion;
a recording unit in which a recording medium that is to record imaging data is to be disposed;
a first heat dissipation member that is provided at an upstream side of the air flow with respect to the air cooling device and that includes a heat dissipation fin for dissipating heat of the recording unit; and
a second heat dissipation member that is a heat dissipation sheet that dissipates heat of the recording unit.

2. The imaging apparatus according to claim 1,
wherein the recording medium is capable of being inserted into and removed from the recording unit.

3. The imaging apparatus according to claim 1,
wherein the rectifying member is a protruding member.

4. The imaging apparatus according to claim 3,
wherein a height dimension of the protruding member is smaller than a width dimension of the protruding member.

5. The imaging apparatus according to claim 1,
wherein the recording unit comprises a medium accommodation portion in which the recording medium is to be accommodated, and a first electronic member that is configured to write the imaging data to the recording medium accommodated in the medium accommodation portion,
the first heat dissipation member dissipates heat of the first electronic member, and
the second heat dissipation member dissipates heat of the medium accommodation portion.

6. The imaging apparatus according to claim 5,
wherein the heat dissipated from the medium accommodation portion includes heat generated from the recording medium.

7. The imaging apparatus according to claim 5,
wherein heat conduction occurs between the medium accommodation portion and the recording medium.

8. The imaging apparatus according to claim 1, further comprising:
a second electronic member that is different from the recording unit; and
a third heat dissipation member that is provided at an upstream side of the air flow with respect to the air cooling device and that includes a heat dissipation fin that dissipates heat of the second electronic member,
wherein an arrangement direction of the fin in the first heat dissipation member and an arrangement direction of the fin in the third heat dissipation member are different from each other.

9. The imaging apparatus according to claim 8,
wherein the first heat dissipation member and the third heat dissipation member are disposed in a same space.

10. The imaging apparatus according to claim 1, comprising:
an imaging unit that includes an imaging element and a third electronic member; and
a fourth heat dissipation member that includes a heat dissipation fin for dissipating heat of the third electronic member,
wherein the fourth heat dissipation member includes a first heat dissipation fin and a second heat dissipation fin, and
at least a part of the air cooling device is provided between the first heat dissipation fin and the second heat dissipation fin.

11. The imaging apparatus according to claim 1, comprising:
a second electronic member that is different from the recording unit;
a third heat dissipation member that is provided at an upstream side of the air flow with respect to the air cooling device and that includes a heat dissipation fin that dissipates heat of the second electronic member;
an imaging unit that includes an imaging element and a third electronic member; and
a fourth heat dissipation member that includes a heat dissipation fin for dissipating heat of the third electronic member,
wherein an arrangement interval of the fin in the first heat dissipation member, an arrangement interval of the fin in the third heat dissipation member, and an arrangement interval of the fin in the fourth heat dissipation member are different from each other.

12. The imaging apparatus according to claim 1,
wherein the air cooling device is an air cooling fan.

13. The imaging apparatus according to claim 1,
wherein the second heat dissipation member is a metal sheet or a graphite sheet.

14. The imaging apparatus according to claim 1,
wherein the recording unit includes a medium accommodation portion in which the recording medium is to be accommodated and that has a lid portion,
the lid portion includes a fixing member that dissipates heat of the medium accommodation portion, and
the second heat dissipation member is connected to the fixing member.

15. The imaging apparatus according to claim 14,
wherein the second heat dissipation member is connected to the first heat dissipation member.

16. An imaging apparatus comprising:
a housing that includes a first intake portion, a second intake portion, and an exhaust portion;
an air cooling device that is provided inside the housing with an interval from the exhaust portion and that is configured to generate an air flow from the first intake portion and the second intake portion toward the exhaust portion;
a rectifying member that is provided at an upstream side of the air flow with respect to the air cooling device and that rectifies intake air from the first intake portion and the second intake portion;
a recording unit in which a recording medium that is to record imaging data is to be inserted into and removed from; and
a second heat dissipation member that is a heat dissipation sheet that dissipates heat of the recording unit.
